(19) United States
(12) Patent Application Publication
(10) Pub. No.: US 2019/0371405 A1
(43) Pub. Date: Dec. 5, 2019

(54) METHOD OF FILLING UP DATA ON OPEN-CHANNEL SOLID STATE DRIVE (SSD) AND AN APPARATUS PERFORMING THE SAME

(71) Applicant: Circuit Blvd., Inc., Sunnyvale, CA (US)

(72) Inventors: Bumsoo KIM, Saratoga, CA (US); Young Tack JIN, Cupertino, CA (US)

(21) Appl. No.: 15/992,187

(22) Filed: May 30, 2018

(51) Int. Cl. G11C 16/08; G11C 8/08; G11C 8/14; G11C 16/04

(52) U.S. Cl. CPC G11C 16/08; G11C 16/0483; G11C 8/14; G11C 8/08

(57) ABSTRACT

Disclosed is a method of filling up data on an open-channel solid state drive (SSD), the method including transmitting information related to a word line to be filled up in response to a geometry command from a host, receiving a word line fill up command from the host based on the information, generating a command to fill up a first word line of a NAND flash memory with pre-defined data in response to the word line fill up command, transmitting the command to a NAND interface (IF) control logic of the controller, generating, by the NAND IF control logic, the pre-defined data in response to the command, transmitting, by the NAND IF control logic, the pre-defined data to a control logic of the NAND flash memory, and filling up, by the control logic, the first word line with the pre-defined data.

### BACKGROUND

### 1. Field

One or more example embodiments relate to a method of filling up data on an open-channel solid state drive (SSD) and an apparatus performing the same.

### 2. Description of Related Art

With the gradual improvement of the performance of a processor, demanding specifications for a memory are increasing. A disk-based storage medium, for example, a hard disk drive (HDD), exhibits an excellent performance in successive address access. However, the performance decreases when accessing a random address.

Thus, a non-volatile memory (NVM) having advantages of a fast speed of response and a low power consumption is used for many computing systems as a storage device that substitutes for the HDD. The NVM includes, for example, a flash memory-based solid state drive (SSD). To improve a bandwidth of such a NVM storage device, studies and developments based on a parallel structure have been conducted. For example, when using a multi-channel structure or multi-way structure for the NVM storage device, the bandwidth improves.

However, in this example, a bandwidth of a host interface used in the HDD-based storage device limits the bandwidth of the NVM storage device. Thus, a peripheral component interconnect express (PCIe) interface was used as the host interface of the NVM storage device. Further, a new NVM express (NVMe) interface was invented for a PCIe interface-based SSD.

Unlike an existing interface that defines a command set and an optimized register and operates with a single input/output (I/O) queue, the NVMe interface has a multi-queue structure and enables an individual queue to be used for each application, thereby increasing I/O parallelism. Further, the NVMe interface supports completion processing with respect to multiple queues/multiple commands with a single interrupt occurring in an SSD.

### SUMMARY

According to an aspect, there is provided a method of filling up data, the method including transmitting, by a central processing unit (CPU) of a controller, information related to a word line to be filled up in response to a geometry command from a host, receiving, by the CPU, a word line fill up command from the host based on the information, generating, by the CPU, a command to fill up a first word line of a NAND flash memory with pre-defined data in response to the word line fill up command, transmitting, by the CPU, the command to a NAND interface (IF) control logic of the controller, generating, by the NAND IF control logic, the pre-defined data in response to the command, transmitting, by the NAND IF control logic, the pre-defined data to a control logic of the NAND flash memory, and filling up, by the control logic of the NAND flash memory, the first word line with the pre-defined data.

The method may further include filling up a second word line of the NAND flash memory with user data.

The second word line may exist subsequent to the first word line, and the filling up of the second word line of the NAND flash memory with the user data may be performed after the filling up, by the control logic of the NAND flash memory, of the first word line with the pre-defined data.

The first word line may exist subsequent to the second word line, and the filling up of the second word line of the NAND flash memory with the user data may be performed before the generating, by the CPU of the controller, of the command to fill up the first word line of the NAND flash memory with the pre-defined data.

The pre-defined data may include an error correction code (ECC) parity, and be scrambled.

The generating, by the CPU of the controller, of the command to fill up the first word line of the NAND flash memory with the pre-defined data may include generating the command based on data stored in firmware of the controller.

The generating, by the NAND IF control logic, of the pre-defined data in response to the command may include generating the pre-defined data based on data stored in firmware of the controller.

According to an aspect, there is provided a method of filling up data, the method including transmitting, by a CPU of a controller, information related to a word line to be filled up in response to a geometry command from a host, receiving, by the CPU, a word line fill up command from the host based on the information, generating, by the CPU, a command to fill up a first word line of a NAND flash memory with pre-defined data in response to the word line fill up command, transmitting, by the CPU, the command to a NAND IF control logic of the controller, transmitting, by the NAND IF control logic, the command to a control logic of the NAND flash memory, generating, by the control logic of the NAND flash memory, the pre-defined data in response to the command, and filling up, by the control logic of the NAND flash memory, the first word line with the pre-defined data.

The method may further include filling up a second word line of the NAND flash memory with user data.

The second word line may exist subsequent to the first word line, and the filling up of the second word line of the NAND flash memory with the user data may be performed after the filling up, by the control logic of the NAND flash memory, of the first word line with the pre-defined data.

The first word line may exist subsequent to the second word line, and the filling up of the second word line of the NAND flash memory with the user data may be performed before the generating, by the CPU of the controller, of the command to fill up the first word line of the NAND flash memory with the pre-defined data.

The pre-defined data may include an ECC parity, and be scrambled.

The generating, by the CPU of the controller, of the command to fill up the first word line of the NAND flash memory with the pre-defined data may include generating the command based on data stored in firmware of the controller.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a block diagram illustrating a solid state drive (SSD) system according to an example embodiment;

FIG. 2 is a block diagram illustrating an SSD device according to an example embodiment;

FIG. 3 illustrates an operation of an SSD device according to an example embodiment;

FIG. 4 illustrates an operation of an SSD device according to an example embodiment;

FIG. 5 illustrates an operation of an SSD device according to an example embodiment;

FIG. 6 illustrates an operation of an SSD device according to an example embodiment;

FIG. 7 illustrates a NAND cell block according to an example embodiment; and

FIG. 8 illustrates a NAND cell block according to an example embodiment.

### DETAILED DESCRIPTION

Hereinafter, reference will now be made in detail to examples with reference to the accompanying drawings, wherein like reference numerals refer to like elements throughout. Various alterations and modifications may be made to the examples. Here, the examples are not construed as limited to the disclosure and should be understood to include all changes, equivalents, and replacements within the idea and the technical scope of the disclosure.

The terminology used herein is for the purpose of describing particular examples only and is not to be limiting of the examples. As used herein, the singular forms “a”, “an”, and “the” are intended to include the plural forms as well, unless the context clearly indicates otherwise. It will be further understood that the terms “include/comprise” and/or “have” when used in this specification, specify the presence of stated features, integers, steps, operations, elements, components, and/or combinations thereof, but do not preclude the presence or addition of one or more other features, numbers, steps, operations, elements, components, and/or groups thereof.

Terms, such as first, second, and the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

Unless otherwise defined, all terms including technical and scientific terms used herein have the same meaning as commonly understood by one of ordinary skill in the art to which examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the examples with reference to the accompanying drawings, like reference numerals refer to like constituent elements and a repeated description related thereto will be omitted. When it is determined detailed description related to a related known function or configuration they may make the purpose of the examples unnecessarily ambiguous in describing the examples, the detailed description will be omitted here.

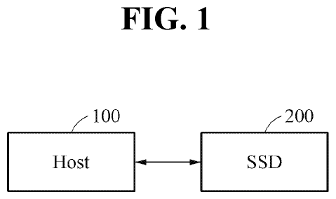

FIG. 1 is a block diagram illustrating a solid state drive (SSD) system according to an example embodiment.

Referring to FIG. 1, an SSD system may include a host 100 and an SSD device 200.

The host 100 may transmit a command to the SSD device 200 based on a command from a user of the SSD system. The SSD device 200 may perform an operation based on the command received from the host 100. For example, the SSD device 200 may perform an operation of reading, writing, or erasing.

The SSD device 200 may not include firmware of a flash translation layer (FTL). For example, the SSD device 200 may be an open-channel SSD device. That is, the SSD device 200 may provide the host 100 with information related to internal parallelism of the SSD device 200 such that the host 100 may perform physical mapping on the SSD device 200. The internal parallelism of the SSD device 200 may be expressed as shown in Table 1 according to versions of open-channel SSD.

Table 1 represents internal parallelism of the SSD device 200 with respect to physical page addresses (PPAs) of Version 1.2 and Version 2.0 of open-channel SSD.

TABLE 1

| | |
|---|---|
| OCSSD ver | PPA(64bit) |

| | | | | | | |
|---|---|---|---|---|---|---|
| 1.2 | ch | lun | pln | blk | pg | sect |

| | | | | |
|---|---|---|---|---|
| 2.0 | group | pu | chunk | logical block |

In a case in which the SSD device 200 complies with Version 1.2 of open-channel SSD, the PPA of the SSD device 200 may include a channel (ch), a logical unit number (lun), a plane (pin), a block (blk), a page (pg), and a sector (sect).

In a case in which the SSD device 200 complies with Version 2.0 of open-channel SSD, the PPA of the SSD device 200 may include a group, a parallel unit (pu), a chunk, and a logical block. In this example, the group may correspond to the channel, the parallel unit may correspond to the logical unit number, the chunk may correspond to the plane and the block, and the logical block may correspond to the page and the sector.

The host 100 and the SSD device 200 may communicate with each other using a software interface. In this example, the software interface may be a non-volatile memory express (NVMe)-based interface. That is, the host 100 may transmit a command to the SSD device 200 through a submission queue. A controller of the SSD device 200 may perform an operation by referring to the submission queue. The controller of the SSD device 200 may report a result of performing the operation to the SSD device 200 through a completion queue.

The submission queue may include a 64-byte submission queue entry including a metadata pointer (MPTR), a data pointer (DPTR), a starting logical block addressing (SLBA), and a number of logical blocks (NLB). The completion queue may include a 16-byte completion queue entry including a status code type (SCT) and a status code (SC).

Admin commands that the host 100 transmits to the SSD device 200 through the submission queue in Version 1.2 of open-channel SSD may be represented as shown in Table 2.

TABLE 2

| | | Opcode | | | |
|---|---|---|---|---|---|
| Opcode | Opcode | (01:00) | | | |
| (07) | (06:02) | Data | NVMe | | |
| Generic | Function | Transfer | Opcode | O/M | Command |
| 1b | 110 00b | 10b | E2h | M | Device Identification |
| 1b | 110 00b | 01b | F1h | O | Set Bad Blocks Table |
| 1b | 110 00b | 10b | F2h | O | Get Bad Blocks Table |

The host 100 may enumerate an inner configuration of the SSD device 200 based on the Admin commands of Table 2, and manage an internal bad block table.

Input/output (I/O) commands that the host 100 transmits to the SSD device 200 through the submission queue in Version 1.2 of open-channel SSD may be represented as shown in Table 3.

TABLE 3

| | | Opcode | | | |
|---|---|---|---|---|---|
| Opcode | Opcode | (01:00) | | | |
| (07) | (06:02) | Data | NVMe | | |
| Generic | Function | Transfer | Opcode | O/M | Command |
| 1b | 001 00b | 00b | 90h | M | Physical Block Erase |
| 1b | 001 00b | 01b | 91h | M | Physical Page Address |
| | | | | | Write |
| 1b | 001 00b | 10b | 92h | M | Physical Page Address |
| | | | | | Read |
| 1b | 001 01b | 01b | 95h | O | Physical Page Address |
| | | | | | Raw Write |
| 1b | 001 01b | 10b | 96h | O | Physical Page Address |
| | | | | | Raw Read |

The host 100 may perform an operation of erasing, writing, or reading based on the I/O commands of Table 3.

Admin commands that the host 100 transmits to the SSD device 200 through the submission queue in Version 2.0 of open-channel SSD may be represented as shown in Table 4.

TABLE 4

| | | Opcode | | | | |
|---|---|---|---|---|---|---|
| Opcode | Opcode | (01:00) | | | Namespace | |
| (07) | (06:02) | Data | NVMe | | Identifier | |
| Generic | Function | Transfer | Opcode | O/M | Used | Command |
| 1b | 110 00b | 10b | E2h | M | Yes | Geometry |
| 0b | 000 00b | 10b | 02h | M | Yes | Get Log Page - |
| | | | | | | Chunk Information |
| 0b | 000 10b | 01b | 09h | M | Yes | Set Features - |
| | | | | | | Media Feedback |
| 0b | 000 10b | 10b | 0Ah | M | Yes | Get Features - |
| | | | | | | Media Feedback |

The host 100 may enumerate an inner configuration of the SSD device 200 based on the Admin commands of Table 4, and read a state of an individual chuck.

I/O commands that the host 100 transmits to the SSD device 200 through the submission queue in Version 2.0 of open-channel SSD may be represented as shown in Table 5.

TABLE 5

| | | Opcode | | | |
|---|---|---|---|---|---|
| Opcode | Opcode | (01:00) | | | |
| (07) | (06:02) | Data | NVMe | | |
| Generic | Function | Transfer | Opcode | O/M | Command |
| 0b | 000 00b | 01b | 01h | M | Write (From NVMe 1.3 |
| | | | | | specification) |
| 0b | 000 00b | 10b | 02h | M | Read (From NVMe 1.3 |
| | | | | | specification) |
| 0b | 000 10b | 01b | 09h | M | Data Management (From |
| | | | | | NVMe 1.3 specification) |
| 1b | 001 00b | 00b | 90h | O | Vector Chunk Reset |
| 1b | 001 00b | 01b | 91h | O | Vector Chunk Write |
| 1b | 001 00b | 10b | 92h | O | Vector Chunk Read |
| 1b | 001 00b | 11b | 93h | O | Vector Chunk Copy |

The host 100 may perform an operation of data management, resetting, writing, reading, or copying based on the I/O commands of Table 5.

Further, the host 100 may preserve user data of the SSD device 200 based on a word line fill up command to fill up with pre-defined data.

First, the host 100 may transmit a geometry command to the SSD device 200. The SSD device 200 may transmit information related to a word line or page to be filled up to the host 100 in response to the geometry command. For example, the information may include information related to a number of word lines or pages to be filled up. Thus, the host 100 may determine the number of word lines or pages to be filled up, and then exactly determine a position at which the user data is to be written.

The host 100 may generate a word line fill up command based on the information, and transmit the word line fill up command to the SSD device 200. The word line fill up command may include a starting address, for example, a position, of a memory region of the SSD device 200 at which filling up with pre-defined data is to be started. In this example, the SSD device 200 may perform a word line fill up operation based on the starting address in response to the word line fill up command.

The pre-defined data may be different from the user data to be written on another word line, refer to a pre-defined pattern, and be construed as dummy data or a dummy pattern.

The pre-defined data may include a randomizer seed and/or an index for pre-defined pattern. For example, the pre-defined data may include “0” or “1” based on the data pattern.

In this example, the pre-defined data may be designated by the host 100. For example, information related to the pre-defined data designated by the host 100 may be incorporated in the word line fill up command and transmitted to the SSD device 200. In another example, the host 100 may transmit a command to designate the pre-defined data separately to the SSD device 200.

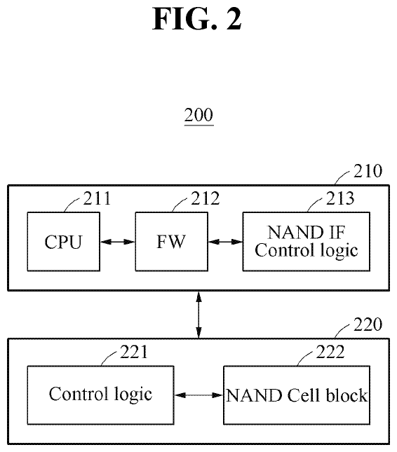

FIG. 2 is a block diagram illustrating an SSD device according to an example embodiment.

Referring to FIG. 2, the SSD device 200 may include a controller 210 and a NAND flash memory 220.

The controller 210 may include a central processing unit (CPU) 211, firmware (FW) 212, and a NAND interface (IF) control logic 213.

The CPU 211 may control an overall operation of the controller 210. For example, the CPU 211 may control the firmware 212 and the NAND IF control logic 213.

The CPU 211 may execute the firmware 212. The firmware 212 may access the NAND flash memory 220 using the NAND IF control logic 213 in response to a command from the host 100. That is, the firmware 212 may perform an operation, for example, initializing (or resetting) the NAND flash memory 220, writing data, or reading data.

The firmware 212 may generate a command to fill up a first word line of the NAND flash memory 220 with the pre-defined data in response to the word line fill up command transmitted from the host 100. In this example, the pre-defined data may be different from user data to be written on another word line, and be construed as dummy data. For example, the pre-defined data may include an error correction code (ECC) parity, and be scrambled. The pre-defined data may prevent a deformation of the user data of a memory block constituting the NAND flash memory 220, and help with efficient preservation of the user data.

A number of pages of a word line may be “1”, “2”, “3”, or “4” according to a single-layer cell (SLC), a multi-layer cell (MLC), a triple-layer cell (TLC), or a quad-layer cell (QLC). Thus, the first word line may include at least one word line, and the generated command may be a command to fill up the at least one word line with the pre-defined data.

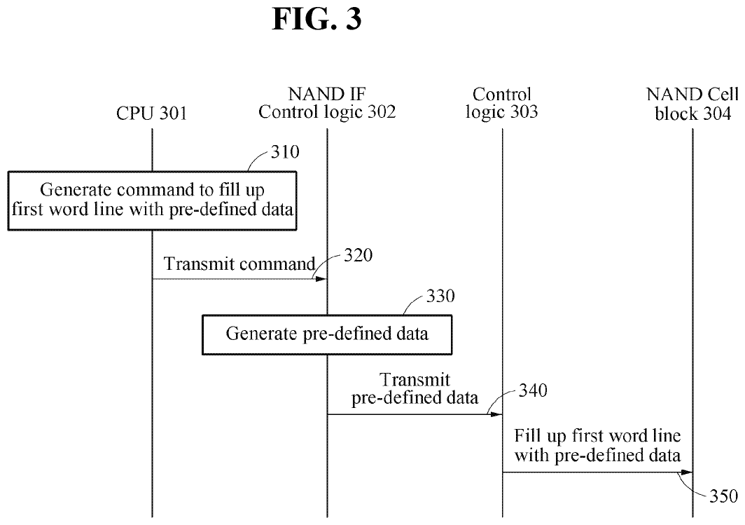

The firmware 212 may transmit the generated command to the NAND IF control logic 213. In this example, the NAND IF control logic 213 may generate the pre-defined data in response to the command, or transmit the command to the NAND flash memory 220. That is, the NAND IF control logic 213 may generate the pre-defined data and transmit the pre-defined data to the NAND flash memory 220, or transmit the command to the NAND flash memory 220 such that the NAND flash memory 220 may generate the pre-defined data. An operation of the NAND IF control logic 213 will be described with reference to FIGS. 3 through 6.

The NAND flash memory 220 may include a control logic 221 and a NAND cell block 222.

The control logic 221 may receive data or a command from the controller 210. For example, the control logic 221 may receive the pre-defined data or a command to generate the pre-defined data from the controller 210.

When the control logic 221 receives the pre-defined data, the control logic 221 may fill up a corresponding word line of the NAND cell block 222 with the pre-defined data. When the control logic 221 receives the command to generate the pre-defined data, the control logic 221 may generate the pre-defined data and fill up a corresponding word line of the NAND cell block 222 with the pre-defined data.

The control logic 221 may fill up the word line of the NAND cell block 222 with the pre-defined data immediately before or after user data is written on another word line. For example, a first word line of the NAND cell block 222 may be filled up with the user data, and a second word line of the NAND cell block 222 may be filled up with the pre-defined data. In another example, the first word line of the NAND cell block 222 may be filled up with the pre-defined data, and the second word line of the NAND cell block 222 may be filled up with the user data. In a case in which the NAND cell block 222 is full of the pre-defined data and the user data, the NAND cell block 222 may be construed as a closing block.

The controller 210 may fill up a word line with the pre-defined data using the firmware 212 or the NAND IF control logic 213, rather than using a static random-access memory (SRAM) or a dynamic random-access memory (DRAM), thereby having an advantage of not using a bandwidth of a main bus of the controller 210.

The pre-defined data generated by the SSD device 200 may be data designated by a host.

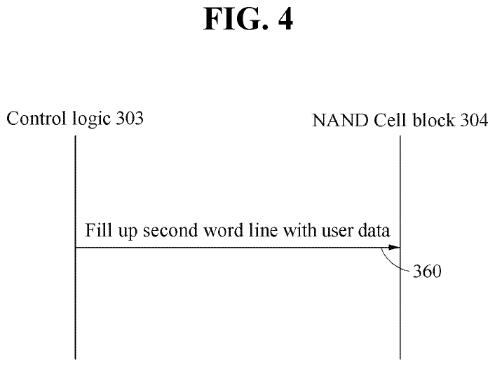

FIGS. 3 and 4 illustrate an operation of an SSD device according to an example embodiment.

Referring to FIGS. 3 and 4, a controller may include a CPU 301 and a NAND IF control logic 302, and a NAND flash memory may include a control logic 303 and a NAND cell block 304.

In operation 310, the CPU 301 may generate a command to fill up a first word line of the NAND cell block 304 with pre-defined data. In this example, the CPU 301 may generate the command by executing firmware. That is, the CPU 301 may generate the command based on data stored in the firmware.

In operation 320, the CPU 301 may transmit the generated command to the NAND IF control logic 302.

In operation 330, the NAND IF control logic 302 may generate the pre-defined data in response to the command In this example, the pre-defined data may be different from user data to be written on another word line, and be construed as dummy data. For example, the pre-defined data may include an ECC parity, and be scrambled. The pre-defined data may prevent a deformation of the user data, and help with efficient preservation of the user data. The NAND IF control logic 302 may generate the pre-defined data based on data stored in the firmware.

In operation 340, the NAND IF control logic 302 may transmit the pre-defined data to the control logic 303. That is, the NAND IF control logic 302 may command the control logic 303 to execute a page program that writes a scrambled data pattern, for a dummy program that fills up a word line with the pre-defined data.

In operation 350, the control logic 303 may fill up the first word line of the NAND cell block 304 with the pre-defined data.

Further, in operation 360, the control logic 303 may fill up a second word line of the NAND cell block 304 with the user data, in response to the command from the controller.

In an example, the second word line may exist subsequent to the first word line, and operation 360 may be performed after operation 350. That is, an SSD device may fill up the first word line with the pre-defined data, and then fill up the second word line with the user data.

In another example, the first word line may exist subsequent to the second word line, and operation 360 may be performed before operation 310. That is, the SSD device may fill up the second word line with the user data, and then fill up the first word line with the pre-defined data.

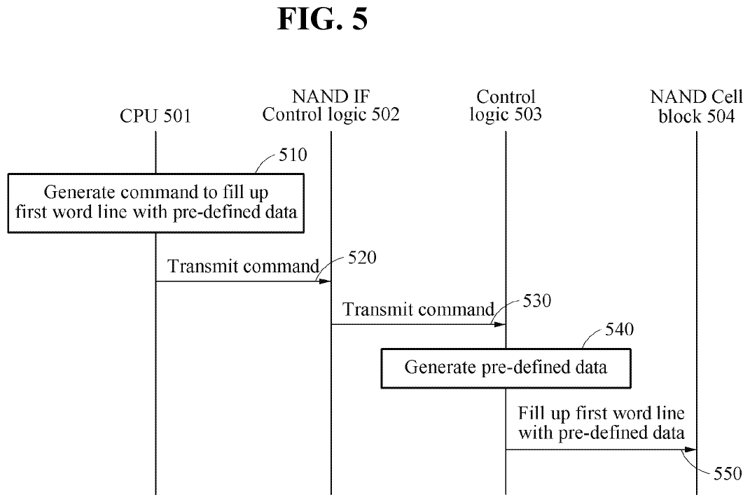

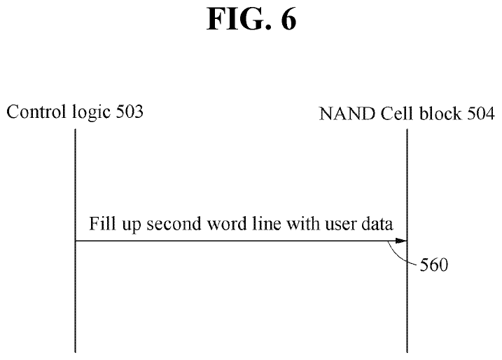

FIGS. 5 and 6 illustrate an operation of an SSD device according to an example embodiment.

Referring to FIGS. 5 and 6, a controller may include a CPU 501 and a NAND IF control logic 502, and a NAND flash memory may include a control logic 503 and a NAND cell block 504.

In operation 510, the CPU 501 may generate a command to fill up a first word line of the NAND cell block 504 with pre-defined data. In this example, the CPU 501 may generate the command by executing firmware. That is, the CPU 501 may generate the command based on data stored in the firmware.

In operation 520, the CPU 501 may transmit the generated command to the NAND IF control logic 502.

In operation 530, the NAND IF control logic 502 may transmit the command to the control logic 503. The NAND IF control logic 502 may transmit the command to the NAND flash memory, instead of transmitting data, thereby alleviating a burden of a bus.

In operation 540, the control logic 503 may generate the pre-defined data in response to the command In this example, the pre-defined data may be different from user data to be written on another word line, and may be construed as dummy data. For example, the pre-defined data may include an ECC parity, and be scrambled. The pre-defined data may prevent a deformation of the user data, and help with efficient preservation of the user data. The NAND IF control logic 502 may generate the pre-defined data based on data stored in the firmware.

The control logic 503 may execute a page program that writes a scrambled data pattern, for a dummy program that fills up a word line with the pre-defined data.

In operation 550, the control logic 503 may fill up the first word line of the NAND cell block 504 with the pre-defined data.

Further, in operation 560, the control logic 503 may fill up a second word line of the NAND cell block 504 with the user data, in response to the command from the controller.

In an example, the second word line may exist subsequent to the first word line, and operation 560 may be performed after operation 550. That is, an SSD device may fill up the first word line with the pre-defined data, and then fill up the second word line with the user data.

In another example, the first word line may exist subsequent to the second word line, and operation 560 may be performed before operation 510. That is, the SSD device may fill up the second word line with the user data, and then fill up the first word line with the pre-defined data.

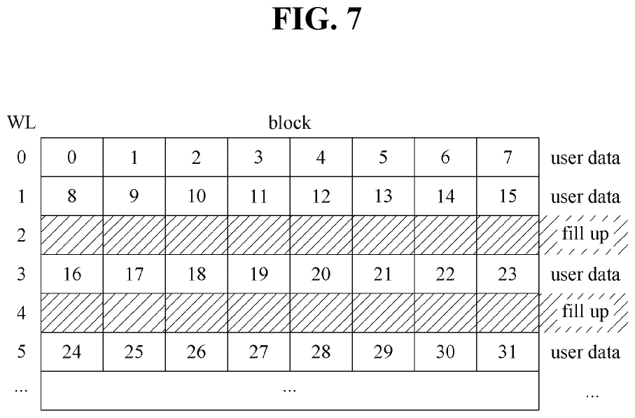

FIG. 7 illustrates a NAND cell block according to an example embodiment.

Referring to FIG. 7, a NAND cell block is illustrated.

A controller of an SSD device may fill up a NAND flash memory with user data and pre-defined data. For example, the SSD device may fill up a zeroth word line WL 0 and a first word line WL 1 with the user data, and fill up a second word line WL 2 with the pre-defined data.

The SSD device may fill up a third word line WL 3 with the user data.

The SSD device may fill up a fourth word line WL 4 with the pre-defined data.

The SSD device may fill up a fifth word line WL 5 with the user data.

In the example of FIG. 7, for ease of description, the SSD device fills up the second word line WL 2 and the fourth word line WL 4 with the pre-defined data. However, example embodiments are not limited thereto. The SSD device may fill up a corresponding word line with the pre-defined data before or after filling up with the user data.

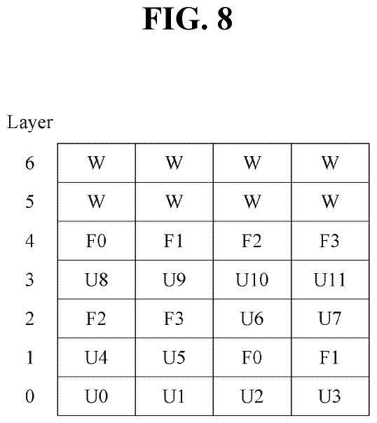

FIG. 8 illustrates a NAND cell block according to an example embodiment.

As described above, a number of pages of a word line may be “1”, “2”, “3”, or “4” according to an SLC, an MLC, a TLC, or a QLC. Unlike FIG. 7, in FIG. 8, a NAND cell block including “4” word lines in each layer is illustrated.

In the example of FIG. 8, W denotes an empty word line, F denotes a word line to be filled up, and U denotes a word line programmed with user data.

A controller of an SSD device may fill up at least one word line of a NAND flash memory with the user data and the pre-defined data.

For example, the controller may fill up word lines F0 and F1 of a first layer with the pre-defined data, fill up word lines F2 and F3 of a second layer with the pre-defined data, and fill up word lines F0 through F3 of a fourth layer with the pre-defined data.

Further, the controller may fill up word lines U0 through U3 of a zeroth layer with the user data, fill up word lines U4 and U5 of the first layer with the user data, fill up word lines U6 and U7 of the second layer with the user data, and fill up word lines U8 through U11 of a third layer with the user data.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

The software may include a computer program, a piece of code, an instruction, or some combination thereof, to independently or collectively instruct and/or configure the processing device to operate as desired, thereby transforming the processing device into a special purpose processor. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the following claims.

1. A method of filling up data, the method comprising:
transmitting, by a central processing unit (CPU) of a controller, information related to a word line to be filled up in response to a geometry command from a host;
receiving, by the CPU, a word line fill up command from the host based on the information;
generating, by the CPU, a command to fill up a first word line of a NAND flash memory with pre-defined data in response to the word line fill up command;
transmitting, by the CPU, the command to a NAND interface (IF) control logic of the controller;
generating, by the NAND IF control logic, the pre-defined data in response to the command;
transmitting, by the NAND IF control logic, the pre-defined data to a control logic of the NAND flash memory; and
filling up, by the control logic of the NAND flash memory, the first word line with the pre-defined data,
wherein the word line fill up command includes a starting address of the first word line.

2. The method of claim 1, further comprising:
filling up a second word line of the NAND flash memory with user data.

3. The method of claim 2, wherein the second word line exists subsequent to the first word line, and
the filling up of the second word line of the NAND flash memory with the user data is performed after the filling up, by the control logic of the NAND flash memory, of the first word line with the pre-defined data.

4. The method of claim 2, wherein the first word line exists subsequent to the second word line, and
the filling up of the second word line of the NAND flash memory with the user data is performed before the generating, by the CPU of the controller, of the command to fill up the first word line of the NAND flash memory with the pre-defined data.

5. The method of claim 1, wherein the pre-defined data includes an error correction code (ECC) parity, and is scrambled.

6. The method of claim 1, wherein the generating, by the CPU of the controller, of the command to fill up the first word line of the NAND flash memory with the pre-defined data comprises generating the command based on data stored in firmware of the controller.

7. The method of claim 1, wherein the generating, by the NAND IF control logic, of the pre-defined data in response to the command comprises generating the pre-defined data based on data stored in firmware of the controller.

8. A method of filling up data, the method comprising:
transmitting, by a central processing unit (CPU) of a controller, information related to a word line to be filled up in response to a geometry command from a host;
receiving, by the CPU, a word line fill up command from the host based on the information;
generating, by the CPU, a command to fill up a first word line of a NAND flash memory with pre-defined data in response to the word line fill up command;
transmitting, by the CPU, the command to a NAND interface (IF) control logic of the controller;
transmitting, by the NAND IF control logic, the command to a control logic of the NAND flash memory;
generating, by the control logic of the NAND flash memory, the pre-defined data in response to the command; and
filling up, by the control logic of the NAND flash memory, the first word line with the pre-defined data,
wherein the word line fill up command includes a starting address of the first word line.

9. The method of claim 8, further comprising:
filling up a second word line of the NAND flash memory with user data.

10. The method of claim 9, wherein the second word line exists subsequent to the first word line, and
the filling up of the second word line of the NAND flash memory with the user data is performed after the filling up, by the control logic of the NAND flash memory, of the first word line with the pre-defined data.

11. The method of claim 9, wherein the first word line exists subsequent to the second word line, and
the filling up of the second word line of the NAND flash memory with the user data is performed before the generating, by the CPU of the controller, of the command to fill up the first word line of the NAND flash memory with the pre-defined data.

12. The method of claim 8, wherein the pre-defined data includes an error correction code (ECC) parity, and is scrambled.

13. The method of claim 8, wherein the generating, by the CPU of the controller, of the command to fill up the first word line of the NAND flash memory with the pre-defined data comprises generating the command based on data stored in firmware of the controller.

14. A non-transitory computer-readable storage medium storing instructions that, when executed by a processor, cause the processor to perform the method of claim 1.
